(19) United States
(12) Patent Application Publication
(10) Pub. No.: US 2009/0039764 A1
(43) Pub. Date: Feb. 12, 2009

(54) Quantum Dot Light-Emitting Diode Comprising Inorganic Electron Transport Layer

(76) Inventors: Kyung Sang Cho, Gyeonggi-do (KR); Byoung Lyong Choi, Seoul (KR); Byung Ki Kim, Gyeonggi-Do (KR); Soon Jae Kwon, Gyeonggi-do (KR)

Correspondence Address: CANTOR COLBURN, LLP, 20 Church Street, 22nd Floor, Hartford, CT, 06103, US

(21) Appl. No.: 10/580,394

(22) PCT Filed: Sep. 16, 2004
(86) PCT No.: PCT/KR05/03084

§ 371 Date: May 22, 2006

(30) Foreign Application Priority Data
Mar. 17, 2005 (KR) 10-2005-0022217

(51) Int. Cl. H01J 1/63

(52) U.S. Cl. 313/504

(57) ABSTRACT

Disclosed herein a quantum dot light-emitting device which has an inorganic electron transport layer. According to the device, an electron transport layer formed by an inorganic materials, thereby providing a high electron transport velocity or electron density and improving a light emitting efficiency. Further, interlayer resistance between electrode and organic-electron transporting layer or between quantum dot light-emitting layer and organic-electron transporting layer is prohibit, thus increasing a light emitting efficiency of diode.

### TECHNICAL FIELD

The present invention relates to a quantum dot light-emitting diode comprising an inorganic electron transport layer, and more particularly to a quantum dot light-emitting diode having a hybrid structure wherein an inorganic thin film is used to constitute an electron transport layer of a quantum dot organic light-emitting diode (OLED) instead of an organic thin film.

### BACKGROUND ART

In general, conventional organic light-emitting diodes (OLEDs) comprise a transparent electrode (e.g., an indium tin oxide (ITO) electrode), an organic hole transport layer, an organic light-emitting layer made of electrically conductive and highly luminescent Alq3, and a low work function electrode (e.g., a Mg:Ag electrode) laminated in this order on a glass substrate.

Since light-emitting layers of conventional OLEDs are made of organic materials, an increase in the current density and driving voltage of the devices is required to achieve high luminance. However, this increase gives rise to degradation of the organic light-emitting materials, and as a result, the service life of the devices is disadvantageously shortened. Particularly, conventional OLEDs for blue light emission suffer from the problem that monomolecular or polymeric organic material light-emitting layers tend to degrade.

Many attempts have been made to solve these problems. For example, U.S. Patent Publication No. 2004/0023010 introduces a quantum dot light-emitting diode having the structure shown in FIG. 1. Quantum dots are used to constitute a light-emitting layer of the quantum dot light-emitting diode, instead of organic materials (e.g., dyes or phosphors) that have been used as materials for the light-emitting layer. The use of quantum dots provide advantages that the quantum dot light-emitting diode is protected against deterioration and oxidation due to heat or moisture and stably achieves blue light emission.

However, defects are likely to occur at the organic-inorganic interface between the quantum dot light-emitting layer and an electron transport layer made of an organic material (e.g., a dye or phosphor) of the quantum dot organic light-emitting diode, disadvantageously leading to poor stability when the device is operated. In addition, since the electron transfer rate and electron density in organic thin films are essentially low, the device has the inherent disadvantage that the electron transport efficiency is lower than the hole transport efficiency in the device.

U.S. Pat. No. 6,023,073 discloses a hybrid organic electroluminescent diode device in which at least one layer of a hole transport layer and an electron transport layer is made of an organic-inorganic alloy containing an inorganic material introduced or dispersed in an organic thin film, instead of an organic thin film. The structure of the device is shown in FIG. 2.

According to this technique, since the electron density and mobility in the organic-inorganic alloy are increased when compared to in an organic thin film, a higher electron or hole transport efficiency can be expected. However, a light-emitting layer of the device is less stable than that of a quantum dot OLED because the light-emitting layer of the device is made of an organic material.

Korean Patent Laid-open No. 2001-71269 discloses an organic electroluminescent device in which both an electron transport layer and a hole transport layer are made of inorganic materials. However, since the inorganic electron transport layer is present between an electrode and an organic light-emitting layer, defects tend to occur at the organic-inorganic interfaces. In addition, considerable fabrication costs of the device are incurred due to the use of a vapor deposition process, such as sputtering or chemical vapor deposition. On the other hand, according to the quantum dot light-emitting diode of the present invention, since an inorganic electron transport layer is formed between a top electrode and quantum dots, no organic-inorganic interface exists. In addition, the inorganic electron transport layer is solution processible by coating processes, such as spin coating.

### DISCLOSURE

### [Technical Problem]

Therefore, the present invention has been made in view of the above problems of the prior art, and it is an object of the present invention to provide an electroluminescent device in which an inorganic thin film is used to constitute an electron transport layer of a quantum dot organic light-emitting diode instead of an organic thin film, thereby facilitating the fabrication of the device at reduced costs and improving the luminescence efficiency of the device.

In accordance with an aspect of the present invention for achieving the above object, there is provided a quantum dot light-emitting diode comprising a pair of top and bottom electrodes and a quantum dot light-emitting layer provided between the electrodes wherein an inorganic electron transport layer is formed between the quantum dot light-emitting layer and the top electrode.

### DESCRIPTION OF DRAWINGS

The above and other objects, features and other advantages of the present invention will be more clearly understood from the following detailed description taken in conjunction with the accompanying drawings, in which:

FIG. 1 is a schematic cross-sectional view of a conventional quantum dot light-emitting diode;

FIG. 2 is a schematic cross-sectional view of a conventional light-emitting diode using an organic-inorganic alloy layer;

FIG. 3 is a schematic cross-sectional view of a quantum dot light-emitting diode comprising an inorganic electron transport layer according to one embodiment of the present invention;

FIG. 4 shows luminescence spectra of a quantum dot light-emitting diode fabricated in Example 2 of the present invention;

FIG. 5 is a graph depicting the current-voltage characteristics of a quantum dot light-emitting diode fabricated in Example 2 of the present invention;

FIG. 6 is a graph showing changes in brightness per unit area in response to changes in the voltage applied to a quantum dot light-emitting diode fabricated in Example 2 of the present invention; and

FIG. 7 is a graph showing changes in brightness per current in response to changes in the voltage applied to a quantum dot light-emitting diode fabricated in Example 2 of the present invention.

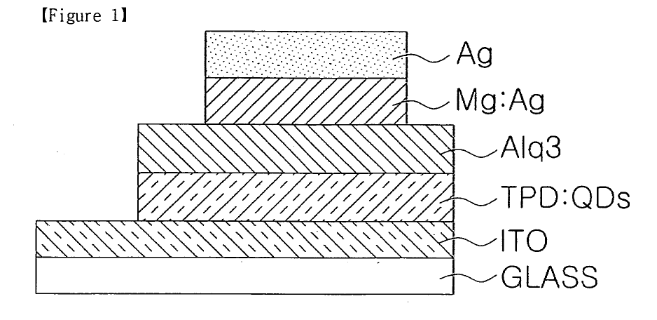

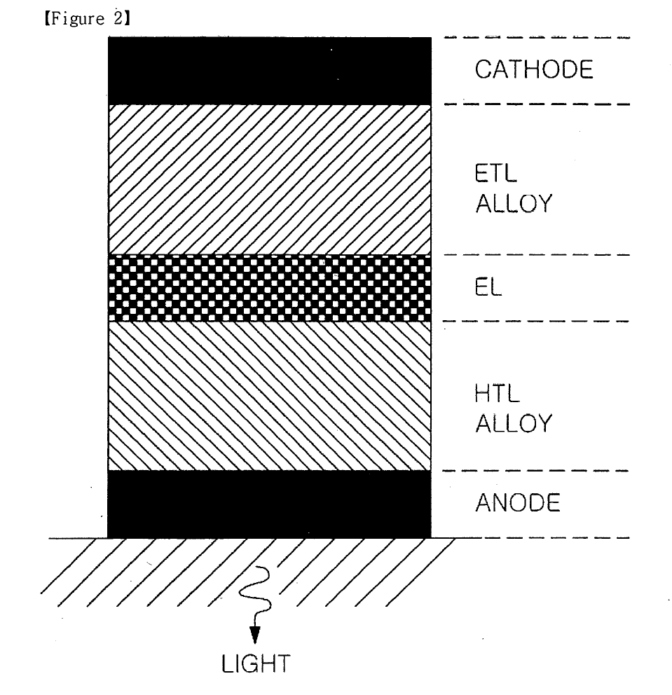

### BEST MODE

The present invention will now be described in more detail.

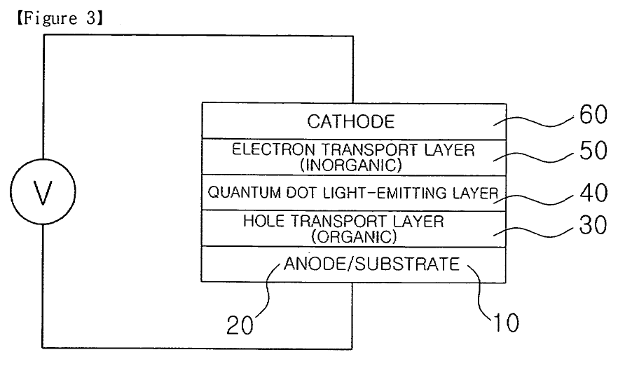

Conventional quantum dot organic light-emitting diodes comprise a hole transport layer and an electron transport layer, both of which are made of organic materials. In contrast, a quantum dot light-emitting diode of the present invention is characterized in that it employs an inorganic thin film as an electron transport layer. FIG. 3 is a schematic view of a quantum dot light-emitting diode according to one embodiment of the present invention. Referring to FIG. 3, the quantum dot light-emitting diode comprises an anode 20, a hole transport layer 30, a quantum dot light-emitting layer 40, an inorganic electron transport layer 50 and a cathode 60 formed in this order on a substrate 10. When a voltage is applied between the two electrodes, the anode 20 injects holes into the hole transport layer 30, while the cathode 60 injects electrons into the electron transport layer 50. The injected holes are combined with the injected electrons at the same molecules to form excitons, and then the excitons are recombined to emit light.

The substrate 10 used in the quantum dot light-emitting diode of the present invention may be a substrate commonly used in the art. A glass or transparent plastic substrate is preferred because of its high transparency, superior surface smoothness, ease of handling, and excellent waterproofness. Specific examples of the transparent substrate include glass, polyethyleneterephthalate, and polycarbonate substrates.

The anode 20 formed on the transparent substrate 10 may be made of an electrically conductive metal or its oxide so that it can easily inject holes. As specific examples of materials for the anode, there may be mentioned indium tin oxide (ITO), indium zinc oxide (IZO), nickel (Ni), platinum (Pt), gold (Au), silver (Ag), and iridium (Ir).

Examples of materials for the hole transport layer 30 include, but are not limited to, poly(3,4-ethylenedioxythiophene) (PEDOT)/polystyrene para-sulfonate (PSS) derivatives, poly-N-vinylcarbazole derivatives, polyphenylenevinylene derivatives, polyparaphenylene derivatives, polymethacrylate derivatives, poly(9,9-octylfluorene) derivatives, poly(spiro-fluorene) derivatives, N,N′-diphenyl-N,N′-bis(3-methylphenyl)-(1,1′-biphenyl)-4,4′-diamine (TPD), N,N′-di(naphthalene-1-yl)-N,N′-diphenyl-benzidine (NPB), tris(3-methylphenylphenylamino)triphenylamine (m-MTDATA), and poly(9,9′-dioctylfluorene-co-N-(4-butylphenyl)diphenylamine (TFB). The thickness of the hole transport layer 30 is preferably in the range of 10 nm to 100 nm.

A material for the quantum dot light-emitting layer 40 is selected from the group consisting of: Group II-VI compound semiconductor nanocrystals, such as CdS, CdSe, ZnS, ZnSe, ZnTe, HgS, HgSe and HgTe; Group III-V compound semiconductor nanocrystals, such as GaP, GaAs, InP and InAs; PbS; PbSe; and PbTe. Further, materials for the quantum dot light-emitting layer may be core-shell structured nanocrystals (for example, CdSe/ZnS, CdS/ZnSe, InP/ZnS, etc.) wherein the core is composed of a nanocrystal (e.g. CdSe, CdS, etc.) having a relatively small bandgap and the shell is composed of nanocrystal (e.g., Zns, ZnSe, etc.) having a relatively large bandgap. The quantum dot light-emitting layer preferably has a thickness of 3 nm to 20 nm.

Specific examples of inorganic materials for the inorganic electron transport layer 50 include, but are not limited to: oxides, such as TiO₂, ZnO, SiO₂, SnO₂, WO₃, Ta₂O₃, BaTiO₃, BaZrO₃, ZrO₂, HfO₂, Al₂O₃, Y₂O₃ and ZrSiO₄; nitrides, such as Si₃N₄; and semiconductor compounds, such as CdS, ZnSe and ZnS. TiO₂, ZrO₂, HfO₂ and Si₃N₄ are preferred. The electron transport layer preferably has a thickness of 10 to 100 nm.

As a material for the cathode 60 for electron injection, there can be used a low work function metal or an oxide thereof that facilitates injection of electrons. Examples of the low work function metal or oxide thereof include, but are not limited to, ITO, Ca, Ba, Ca/Al, LiF/Ca, LiF/Al, BaF₂/Al, BaF₂/Ca/Al, Al, Mg, and Ag:Mg alloys. The thickness of the cathode is preferably in the range of 50 nm to 200 nm.

The quantum dot light-emitting diode of the present invention is fabricated in accordance with the following procedure. First, a hole transport layer 30 is formed on an anode 20 into which holes are injected by various coating processes, including spin coating, casting, printing, spraying, vacuum deposition, sputtering, chemical vapor deposition (CVD), and e-beam evaporation. Then, a quantum dot light-emitting layer 40 is formed on the hole transport layer 30 by spin coating, which is the same coating process employed in the fabrication of conventional quantum dot organic light-emitting diodes. Alternatively, an organic high- or low-molecular weight material for the hole transport layer is dissolved in a solvent, such as chloroform or chlorobenzene, mixed with a proper amount of a solution of quantum dots, followed by coating to form a film in which the material for the hole transport layer is mixed with the quantum dots or to form a coating structure in which the quantum dots are coated on the hole transport layer.

Thereafter, an inorganic electron transport layer 50 is formed on the quantum dot light-emitting layer 40. To this end, an appropriate inorganic material for the inorganic electron transport layer is selected, and coated on the quantum dot light-emitting layer 40 to form a film. At this time, the coating can be achieved by a vapor coating process, such as chemical vapor deposition (CVD), sputtering, e-beam evaporation or vacuum deposition, or a solution coating process, such as sol-gel coating, spin coating, printing, casting or spraying, by which an inorganic thin film can be formed at a lower temperature and at lower cost. Subsequently, the film is annealed at from about 50° C. to about 120° C. to form the desired inorganic electron transport layer. The inorganic electron transport layer thus formed has a good crystallinity without occurrence of defects in the quantum dot light-emitting layer 40 or the organic hole transport layer 30. Finally, a cathode 60 into which electrons are injected is laminated on the inorganic electron transport layer.

As described above, the quantum dot light-emitting diode of the present invention may be fabricated by sequentially forming the anode 20, the hole transport layer 30, the quantum dot light-emitting layer 40, the inorganic electron transport layer 50, and the cathode 60. Alternatively, as is well known to those skilled in the art, the quantum dot light-emitting diode may be fabricated by sequentially forming the cathode 60, the inorganic electron transport layer 50, the quantum dot light-emitting layer 40, the hole transport layer 30, and the anode 20. No special apparatus or process is needed for the fabrication of the quantum dot light-emitting diode according to the present invention, except the formation of the inorganic electron transport layer. The quantum dot light-emitting diode of the present invention can be fabricated by general procedures using quantum dots as light-emitting materials.

### MODE FOR INVENTION

The present invention will now be described in more detail with reference to the following examples. However, these examples are given for the purpose of illustration and are not to be construed as limiting the scope of the invention.

### Preparative Example 1

### Preparation of CdS Quantum Dots

2.5 ml of trioctyl amine was placed in a 25 ml flask equipped with a reflux condenser, and the temperature was adjusted to 180° C. with stirring. A solution of cadmium dithio diethyl carbamate (50 mg) in 0.9 ml of trioctyl phosphine was rapidly fed into the flask. After the reaction was continued for 10 minutes, a solution of zinc dithio diethyl carbamate (20 mg) in trioctyl phosphine (0.3 ml) was slowly added dropwise to the reaction mixture. About 5 minutes after the addition, the reaction temperature was lowered and the reaction was quenched by the addition of ethanol. The resulting reaction mixture was centrifuged to separate quantum dots. The quantum dots were dispersed in toluene.

### Example 1

### Fabrication of Quantum Dot Light-Emitting Diode

A glass substrate on which ITO was patterned was sequentially washed with a neutral detergent, deionized water, water and isopropyl alcohol, and then the resulting substrate was treated with UV-ozone. A hole transport layer and a quantum dot thin film were sequentially formed on the ITO substrate. Specifically, (N,N′-diphenyl-N,N′-bis(3-methylphenyl)-(1,1′-biphenyl)-4,4′-diamine (TPD) was dissolved in chloroform to prepare a solution (1 wt %). Separately, the CdS quantum dots prepared in Preparative Example 1 were dispersed in chloroform to prepare a dispersion (1 wt %). The TPD solution and the CdS dispersion were mixed in a ratio of 1:1. The resulting solution was spin-coated on the ITO substrate at about 2,000 rpm for one minute and dried to form a TPD/quantum dot thin film having a thickness of about 45 nm.

*44TiO₂ was coated to a thickness of 40 nm on top of the dried quantum dot light-emitting layer by e-beam evaporation to form an electron transport layer. LiF and aluminum were sequentially deposited to thicknesses of 5 nm and 200 nm, respectively, on the electron transport layer to form an electrode, completing the fabrication of the final quantum dot light-emitting diode.

When an electric field was applied to the quantum dot light-emitting diode, the diode showed diode characteristics. When the diode was biased with the ITO substrate on a positive side and the aluminum electrode on a negative side, the current was increased with increasing voltage and light emission was observed in an ordinary room.

### Example 2

### Fabrication of Quantum Dot Light-Emitting Diode

A TiO₂ precursor sol (DuPont Tyzor, BTP, 2.5 wt % in buthanol) was spin-coated on a patterned ITO cathode at 2,000 rpm under a nitrogen atmosphere for 30 seconds, dried under a nitrogen atmosphere for 5 minutes, and annealed at 150° C. for 15 minutes to form an amorphous TiO₂ thin film having a thickness of about 20 nm. A solution (0.3 wt %) of red CdSe/ZnS core/shell structured nanocrystals (Evidot 630 nm absorbance) (Evidot Red (CdSe/ZnS), Evident Technology) was spin-coated on the TiO₂ thin film at 2,000 rpm for 30 seconds, and dried at 50° C. for 5 minutes. N,N′-di(naphthalen-1-yl)-N-N′-diphenyl-benzidine (NPB) was deposited to a thickness of about 40 nm on the quantum dot light-emitting layer using a thermal evaporator in a glove box to form an organic thin film. Finally, Au was deposited to a thickness of 100 nm using a patterned mask to form an electrode, completing the fabrication of a quantum dot light-emitting diode. The diode was sealed using encap glass to protect it against oxygen and moisture. After the diode was taken out of the glove box, the characteristics of the diode were measured.

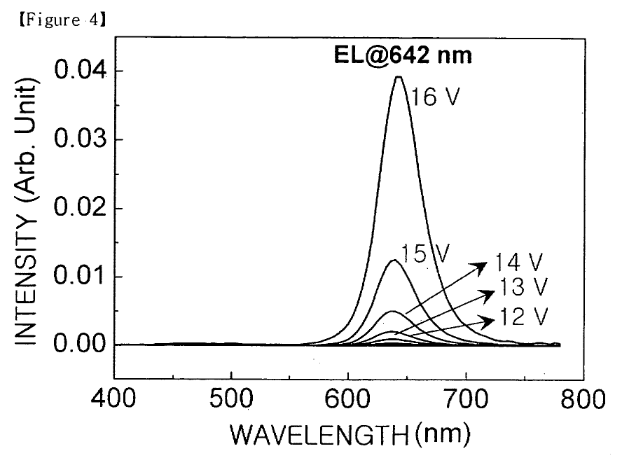

The luminescence intensity of the quantum dot light-emitting diode fabricated in Example 2 was measured at ambient temperature and pressure. The results are shown in FIG. 4. The graph shows that the luminescence intensity of the device increases with increasing voltage. The device was measured to have a light-emitting area of 4 mm².

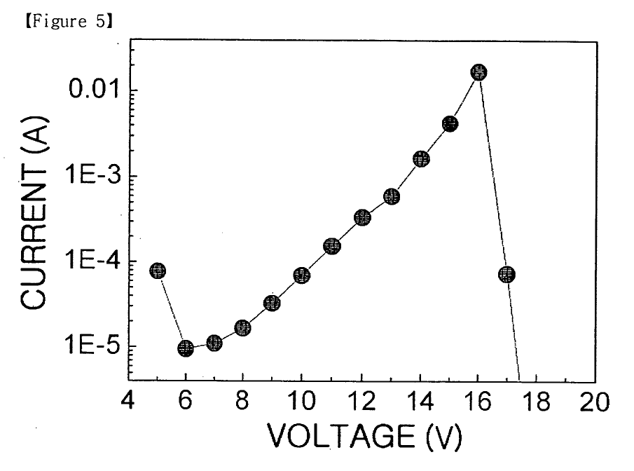

FIG. 5 is a graph depicting the current-voltage characteristics of the quantum dot light-emitting diode fabricated in Example 2, as measured at ambient temperature and pressure. It can be seen from the graph that the current increases exponentially with increasing voltage in the range of 6 to 16V.

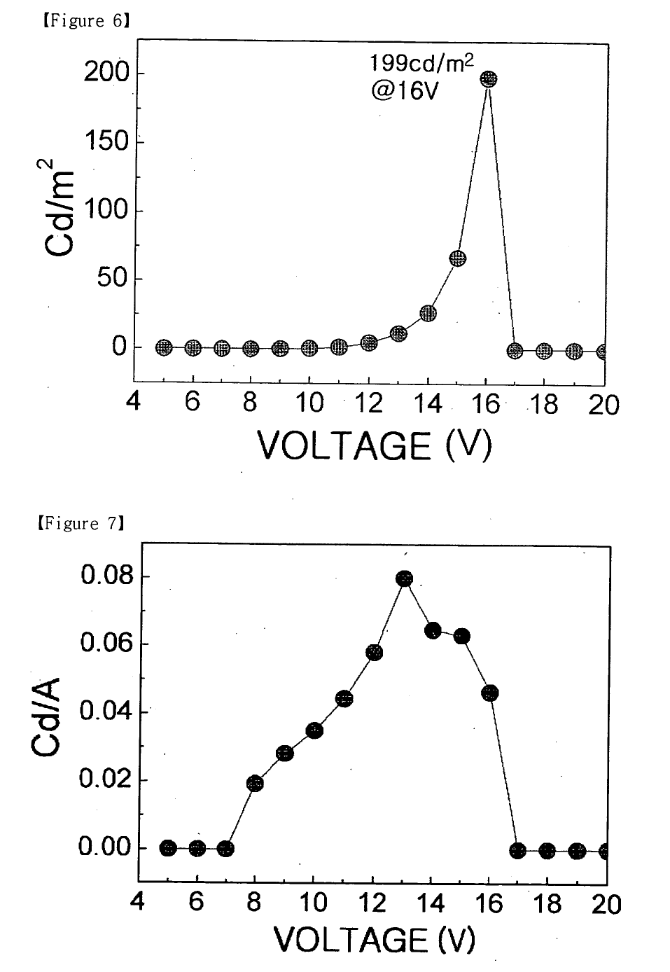

FIG. 6 is a graph showing changes in brightness per unit area, as measured at ambient temperature and pressure, in response to changes in the voltage applied to the quantum dot light-emitting diode fabricated in Example 2. The graph shows that the brightness increases exponentially with increasing voltage. The device was measured to have a maximum intensity of 200 Cd/m² at 16V.

FIG. 7 is a graph showing changes in brightness per current, as measured at ambient temperature and pressure, in response to changes in the voltage applied to the quantum dot light-emitting diode fabricated in Example 2. The graph shows that the efficiency of the device increases steadily with increasing voltage until it reaches a maximum at 13V and thereafter begins to decreases.

### INDUSTRIAL APPLICABILITY

As apparent from the above description, the quantum dot light-emitting diode of the present invention provides the following advantageous effects.

1) The use of an inorganic semiconductor or oxide as a material for an electron transport layer instead of an organic thin film increases the transport rate and efficiency of electrons in the electron transport layer and improves the stability of the device.

2) In the case where a hole transport layer, a quantum dot light-emitting layer and an electron transport layer are sequentially formed on an ITO substrate, packaging effects of devices, such as conventional quantum dot light-emitting diodes and organic light-emitting diodes, can be provided due to the formation of the inorganic thin film, thereby improving the stability of the devices and enabling the fabrication of the devices by simplified procedure at reduced costs.

3) The organic-inorganic interfaces between an organic electron transport layer and an inorganic light-emitting layer and between a top electrode and the electron transport layer in a conventional organic light-emitting diode are replaced by the inorganic-inorganic interfaces in the quantum dot light-emitting diode of the present invention. Accordingly, interfacial resistance essentially caused by the presence of the organic-inorganic interfaces is lowered and thus an increase in the efficiency of the device can be anticipated.

4) Since the inorganic electron transport layer of the quantum dot light-emitting diode according to the present invention is solution processible by a sol-gel process and can be crystallized at a sintering temperature of 150° C. or below, the quantum dot light-emitting diode can be fabricated in a large area at low costs.

Although the preferred embodiments of the present invention have been disclosed for illustrative purposes, those skilled in the art will appreciate that various modifications and variations are possible, without departing from the scope and spirit of the invention as disclosed in the appended claims. Accordingly, such modifications and variations are intended to come within the scope of the appended claims.

1. A quantum dot light-emitting diode comprising a pair of top and bottom electrodes and a quantum dot light-emitting layer provided between the electrodes wherein an inorganic electron transport layer is formed between the quantum dot light-emitting layer and the top electrode.

2. The quantum dot light-emitting diode according to claim 1, wherein the diode comprises an anode, a hole transport layer, a quantum dot light-emitting layer, an inorganic electron transport layer and a cathode formed in this order on a substrate.

3. The quantum dot light-emitting diode according to claim 1, wherein the inorganic electron transport layer is made of an oxide selected from the group consisting of TiO₂, ZnO, SiO₂, SnO₂, WO₃, Ta₂O₃, BaTiO₃, BaZrO₃, ZrO₂, HfO₂, Al₂O₃, Y₂O₃ and ZrSiO₄; the nitride Si₃N₄; or a semiconductor compound selected from the group consisting of CdS, ZnSe and ZnS.

4. The quantum dot light-emitting diode according to claim 1, wherein the quantum dot light-emitting layer is made of a material selected from the group consisting of: Group II-VI compound semiconductor nanocrystals, including CdS, CdSe, CdTe, ZnS, ZnSe, ZnTe, HgS, HgSe and HgTe; Group III-V compound semiconductor nanocrystals, including GaN, GaP, GaAs, InP and InAs; PbS; PbSe; PbTe; CdSe/ZnS; CdS/ZnSe; and InP/ZnS.

5. The quantum dot light-emitting diode according to claim 1, wherein the inorganic electron transport layer is formed by a solution coating process selected from the group consisting of sol-gel coating, spin coating, printing, casting and spraying, or a vapor coating process selected from the group consisting of chemical vapor deposition (CVD), sputtering, e-beam evaporation and vacuum deposition.

6. The quantum dot light-emitting diode according to claim 2, wherein the hole transport layer is made of a material selected from the group consisting of poly(3,4-ethylenedioxythiophene) (PEDOT)/polystyrene para-sulfonate (PSS) derivatives, poly-N-vinylcarbazole derivatives, polyphenylenevinylene derivatives, polyparaphenylene derivatives, polymethacrylate derivatives, poly(9,9-octylfluorene) derivatives, poly(spiro-fluorene) derivatives, N,N′-diphenyl-N,N′-bis(3-methylphenyl)-(1,1′-biphenyl)-4,4′-diamine (TPD), N,N′-di(naphthalene-1-yl)-N,N′diphenyl-benzidine (NPB), tris(3-methylphenylphenylamino)-triphenylamine (m-MTDATA), and poly(9,9′-dioctylfluorene-co-N-(4-butylphenyl)diphenylamine (TFB).

7. The quantum dot light-emitting diode according to claim 2, wherein the inorganic electron transport layer is made of an oxide selected from the group consisting of TiO₂, ZnO, SiO₂, SnO₂, WO₃, Ta₂O₃, BaTiO₃, BaZrO₃, ZrO₂, HfO₂, Al₂O₃, Y₂O₃ and ZrSiO₄; the nitride Si₃N₄; or a semiconductor compound selected from the group consisting of CdS, ZnSe and ZnS.

8. The quantum dot light-emitting diode according to claim 2, wherein the quantum dot light-emitting layer is made of a material selected from the group consisting of: Group II-VI compound semiconductor nanocrystals, including CdS, CdSe, CdTe, ZnS, ZnSe, ZnTe, HgS, HgSe and HgTe; Group III-V compound semiconductor nanocrystals, including GaN, GaP, GaAs, InP and InAs; PbS; PbSe; PbTe; CdSe/ZnS; CdS/ZnSe; and InP/ZnS.

9. The quantum dot light-emitting diode according to claim 2, wherein the inorganic electron transport layer is formed by a solution coating process selected from the group consisting of sol-gel coating, spin coating, printing, casting and spraying, or a vapor coating process selected from the group consisting of chemical vapor deposition (CVD), sputtering, e-beam evaporation and vacuum deposition.
